(19) United States
(12) Patent Application Publication
(10) Pub. No.: US 2026/0342330 A1
(43) Pub. Date: Oct. 29, 2026

(54) POWER-ON RESET CIRCUIT BASED ON RESISTANCE VOLTAGE DIVIDER DETECTION

(71) Applicant: Xiamen Industrial Technology Research Institute Co.,Ltd., Xiamen (CN)

(72) Inventors: Lixia Bai, Xiamen (CN); Guangwei Zhao, Xiamen (CN); Wenming Li, Hsinchu (CN); Meidong Liu, Xiamen (CN); Tianlong Pan, Xiamen (CN); Jiayu Yin, Xiamen (CN); Zhexin Zheng, Zhangzhou (CN); Hezuo Hong, Xiamen (CN)

(21) Appl. No.: 19/702,044

(22) Filed: Jun. 9, 2026

Related U.S. Application Data
(63) Continuation of application No. PCT/CN2026/096984, filed on May 14, 2026.

(30) Foreign Application Priority Data
Dec. 11, 2025 (CN) 202511869116.3

(51) Int. Cl. H03K 17/22; G01R 19/00; H03K 19/20

(52) U.S. Cl. CPC H03K 17/223; G01R 19/0038; H03K 19/20

(57) ABSTRACT

Provided is a power-on reset circuit based on resistance voltage division detection, which includes a first detection unit that detects an input first bias signal to obtain a first detection voltage; a second detection unit detects an input second bias signal to obtain a second detection voltage; and a logic comparison unit that includes a NAND gate, where a first input terminal of the NAND gate is connected to the first detection unit, a second input terminal of the NAND gate is connected to the second detection unit, and the NAND gate outputs a corresponding reset signal based on the first detection voltage and the second detection voltage; so as to achieve fast power-on speed and reduce the overall circuit area.

### CROSS-REFERENCE TO RELATED APPLICATIONS

This application is a continuation of International Application No. PCT/CN 2026/096984, filed on May 14, 2026, which claims priority to Chinese Patent Application No. 202511869116.3, filed on Dec. 11, 2025. Both of which are hereby incorporated by reference in their entireties.

### TECHNICAL FIELD

The present disclosure relates to the field of reset circuit technologies, and in particular, to a power-on reset circuit based on resistance voltage divider detection.

### BACKGROUND

In related technologies, existing power-on reset circuits need to wait for Pbias and Nbias to start during the power-on process. After the circuit is started, a comparator COMP is used to compare the voltage and the output result is used as the power-on reset signal; this scheme requires strict timing control between the circuit start-up time (stable timing of PBIAS and NBIA voltages) and the detection sampling time of voltages IP and IN (stable speed of R1 and R2), otherwise it will result in incorrect comparator output results and POR power-on failure; besides that, the offset of the comparator itself can make it difficult to control the timing of the entire circuit, resulting in a more complex circuit implementation.

### SUMMARY

The present disclosure aims to at least partially solve one of the technical problems with the above-mentioned technology. Therefore, one objective of the present disclosure is to provide a power-on reset circuit based on resistance voltage division detection, which detects voltage through resistance voltage division and replaces the comparator with a NAND gate to achieve fast power-on speed and reduced overall circuit area.

To achieve the above objectives, an embodiment of the present disclosure provides a power-on reset circuit based on resistance voltage division detection, including: a first detection unit, configured to detect an input first bias signal to obtain a first detection voltage, a second detection unit, configured to detect an input second bias signal to obtain a second detection voltage, and a logic comparison unit, which includes a NAND gate, where a first input terminal of the NAND gate is connected to the first detection unit, a second input terminal of the NAND gate is connected to the second detection unit, and the NAND gate outputs a corresponding reset signal based on the first detection voltage and the second detection voltage; as a result, the power-on speed is fast and the overall circuit area is reduced.

In addition, the power-on reset circuit based on resistance voltage division detection provided in the embodiments of the present disclosure may also have the following additional technical features.

In some embodiments of the present disclosure, the first detection unit includes: a first resistor voltage divider unit, configured to divide and sample an input power supply to obtain a first initial detection voltage, a first start-up control unit, which is connected to the first resistor voltage divider unit to conduct according to the first initial detection voltage, and a first charge and discharge unit, which is connected to the first start-up control unit; after the first start-up control unit is conducted, the first charge and discharge unit obtains a corresponding first detection voltage based on the first bias signal.

In some embodiments of the present disclosure, the first resistance voltage division unit includes: a first resistor, where one end of the first resistor is grounded; and a second resistor, one end of the second resistor is connected to the other end of the first resistor, and the other end of the second resistor is connected to a power source.

In some embodiments of the present disclosure, the first start-up control unit includes: a first capacitor, where one end of the first capacitor is connected between the first resistor and the second resistor, and the other end of the first capacitor is grounded, and a first MOS transistor, where a gate of the first MOS transistor is connected between the first resistor and the second resistor, and a source of the first MOS transistor is connected to ground.

In some embodiments of the present disclosure, the first charge and discharge unit includes: a second MOS transistor, where a gate of the second MOS transistor is connected to a start-up and bias circuit generator unit to receive the first bias signal, a source of the second MOS transistor is connected to the power supply, and a drain of the second MOS transistor is connected to a drain of the first MOS transistor, and a second capacitor, where one end of the second capacitor is connected to the power supply, and the other end of the second capacitor is connected between the drain of the second MOS transistor and the drain of the first MOS transistor.

In some embodiments of the present disclosure, the second detection unit includes: a second resistor voltage divider unit, configured to divide and sample an input power supply to obtain a second initial detection voltage, a second start-up control unit, which is connected to the second resistor voltage divider unit to conduct according to the second initial detection voltage, and a second charge and discharge unit, which is connected to the second start-up control unit; after the second start-up control unit is conducted, the second charge and discharge unit obtains a corresponding second detection voltage based on the second bias signal.

In some embodiments of the present disclosure, the second resistance voltage division unit includes: a third resistor, where one end of the third resistor is grounded; a fourth resistor, one end of the fourth resistor is connected to the other end of the third resistor, and the other end of the fourth resistor is connected to the power supply.

In some embodiments of the present disclosure, the second start-up control unit includes: a third capacitor, one end of the third capacitor is connected between the third resistor and the fourth resistor, and the other end of the third capacitor is connected to the power supply; a third MOS transistor, a gate of the third MOS transistor is connected between the third resistor and the fourth resistor, and a source of the third MOS transistor is connected to the power supply.

In some embodiments of the present disclosure, the second charge and discharge unit includes: a fourth MOS transistor, where a gate of the fourth MOS transistor is connected to a start-up and bias circuit generator unit to receive the second bias signal, a source of the fourth MOS transistor is connected to ground, and a drain of the fourth MOS transistor is connected to a drain of the third MOS transistor; a fourth capacitor, where one end of the fourth capacitor is connected to ground and the other end the fourth capacitor is connected between the drain of the fourth MOS transistor and the drain of the third MOS transistor.

In some embodiments of the present disclosure, the logic comparison unit further includes a first inverter, a second inverter, and a third inverter, where an input terminal of the first inverter is connected to an output terminal of the first detection unit, an output terminal of the first inverter is connected to the first input terminal of the NAND gate, an input terminal of the second inverter is connected to an output terminal of the second detection unit, an output terminal of the second inverter is connected to an input terminal of the third inverter, and an output terminal of the third inverter is connected to the second input terminal of the NAND gate.

### BRIEF DESCRIPTION OF DRAWINGS

FIG. 1 is a circuit schematic diagram of the existing power-on reset circuit.

FIG. 2 is a circuit schematic diagram of a power-on reset circuit based on resistance voltage division detection according to an embodiment of the present disclosure.

### DESCRIPTION OF EMBODIMENTS

The embodiments of the present disclosure are described in detail below, and examples of the embodiments are shown in the accompanying drawings, where the same or similar reference numerals throughout represent the same or similar elements or components with the same or similar functions. The embodiments described below with reference to the accompanying drawings are exemplary and intended to explain the present disclosure, and should not be construed as limiting the present disclosure.

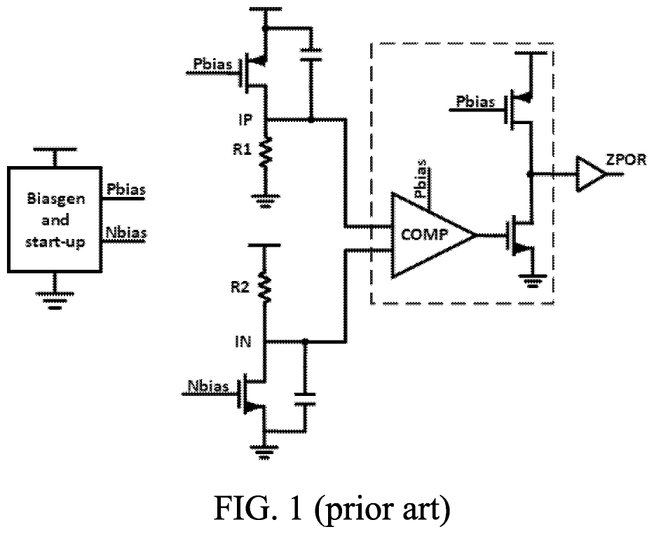

In related technologies, as shown in FIG. 1, a Power-On Reset, (POR) startup circuit in the prior art requires a comparator for voltage detection. The timing error between signals generated by the startup circuit and the Biasgen circuit, as well as an offset of the comparator itself, are difficult to eliminate, resulting in a complex circuit implementation; to this end, the present application provides a power-on reset circuit based on resistance voltage division detection, which improves the power-on speed of the circuit through resistance voltage division detection. A logic NAND gate replaces a comparator circuit, thereby eliminating timing errors in the circuit and the impact of comparator offset, making power-on reset safer; the overall circuit structure is simple and easy to implement, thereby reducing the area.

In order to better understand the above technical solution, exemplary embodiments of the present disclosure will be described in more detail below with reference to the accompanying drawings. Although exemplary embodiments of the present disclosure are shown in the accompanying drawings, it should be understood that the present disclosure may be implemented in various forms and should not be limited by the embodiments described herein. On the contrary, these embodiments are provided to enable a more thorough understanding of the present disclosure and to fully convey the scope of the present disclosure to those skilled in the art.

In order to better understand the above technical solution, a detailed explanation of the above technical solution will be provided below in combination with the accompanying drawings in the specification and specific implementation modes.

Below, the power-on reset circuit based on resistance voltage division detection in the embodiment of the present disclosure will be described with reference to the accompanying drawings.

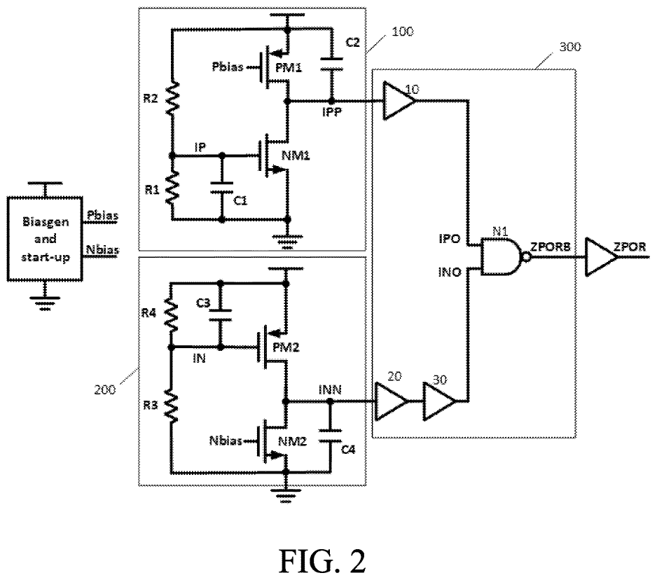

Referring to FIG. 2, the power-on reset circuit based on resistance voltage division detection provided in the embodiment of the present disclosure includes a first detection unit 100, a second detection unit 200, and a logic comparison unit 300.

Where the first detection unit 100 detects an input first bias signal Pbias to obtain a first detection voltage IPP.

As an embodiment, the first detection unit 100 includes a first resistor voltage divider unit, a first start-up control unit, and a first charge and discharge unit. The first resistor voltage divider unit divides and samples the input power supply to obtain a first initial detection voltage; the first start-up control unit is connected to the first resistor voltage divider unit to conduct according to the first initial detection voltage; the first charge and discharge unit is connected to the first start-up control unit, and the first charge and discharge unit obtains the corresponding first detection voltage based on the first bias signal after the first start-up control unit is conducted.

In an implementation mode, the first resistor voltage divider unit includes a first resistor R1 and a second resistor R2; one end of the first resistor R1 is grounded; one end of the second resistor R2 is connected to the other end of the first resistor R1, and the other end of the second resistor R2 is connected to a power supply.

In an implementation mode, the first start-up control unit includes a first capacitor C1 and a first MOS transistor NM1; one end of the first capacitor C1 is connected between the first resistor R1 and the second resistor R2, and the other end of the first capacitor C1 is grounded; a gate of the first MOS transistor NM1 is connected between the first resistor R1 and the second resistor R2, and a source of the first MOS transistor NM1 is connected to ground.

That is to say, during a process of powering on the power supply VDD, voltage division sampling is performed through a resistor, and the first capacitor C1 is charged to make the first MOS transistor NM1 conductive through the first initial detection voltage IP.

In an implementation mode, the first charge and discharge unit includes a second MOS transistor PM1 and a second capacitor C2; a gate of the second MOS transistor PM1 is connected to a start-up and bias circuit generator unit to receive the first bias signal Pbias, a source of the second MOS transistor PM1 is connected to the power supply, and a drain of the second MOS transistor PM1 is connected to a drain of the first MOS transistor NM1; one end of the second capacitor C2 is connected to the power supply, and the other end of the second capacitor C2 is connected between the drain of the second MOS transistor PM1 and the drain of the first MOS transistor NM1.

Where the second detection unit 200 detects the input second bias signal Nbias to obtain a second detection voltage INN.

As an embodiment, the second detection unit 200 includes a second resistor voltage divider unit, a second start-up control unit, and a second charge and discharge unit. The second resistor voltage divider unit divides and samples the input power supply to obtain a second initial detection voltage; the second start-up control unit is connected to the second resistor voltage divider unit to conduct according to the second initial detection voltage; the second charge and discharge unit is connected to the second start-up control unit, and the second charge and discharge unit obtains the corresponding second detection voltage based on the second bias signal after the second start-up control unit is conducted.

In an implementation mode, the second resistor voltage divider unit includes a third resistor R3 and a fourth resistor R4; one end of the third resistor R3 is grounded; one end of the fourth resistor R4 is connected to the other end of the third resistor R3, and the other end of the fourth resistor R4 is connected to the power supply.

In an implementation mode, the second start-up control unit includes a third capacitor C3 and a third MOS transistor PM2; one end of the third capacitor C3 is connected between the third resistor R3 and the fourth resistor R4, and the other end of the third capacitor C3 is connected to the power supply; a gate of the third MOS transistor PM2 is connected between the third resistor R3 and the fourth resistor R4, and a source of the third MOS transistor PM2 is connected to the power supply.

That is to say, during a process of powering on the power supply VDD, voltage division sampling is performed through a resistor, and the third capacitor C3 is charged to make the third MOS transistor PM2 conductive through the second initial detection voltage IN.

In an implementation mode, the second charge and discharge unit includes a fourth MOS transistor NM2 and a fourth capacitor C4; a gate of the fourth MOS transistor NM2 is connected to the start-up and bias circuit generator unit to receive a second bias signal Nbias, a source of the fourth MOS transistor NM2 is connected to ground, and a drain of the fourth MOS transistor NM2 is connected to a drain of the third MOS transistor PM2; one end of the fourth capacitor C4 is connected to ground, and the other end of the fourth capacitor C4 is connected between the drain of the fourth MOS transistor NM2 and the drain of the third MOS transistor PM2.

That is to say, after the first MOS transistor NM1 and the third MOS transistor PM2 are turned on, wait for the bias circuit generator Biasgen and the startup circuit Star-up to start. After the first bias signal Pbias and the second bias signal Nbias arrive, IPP and INN are charged through the second capacitor C2 and the fourth capacitor C4.

In an implementation mode, when the first MOS transistor NM1 is conductive, the second capacitor C2 discharges, and when the first MOS transistor NM1 is non-conductive, the second capacitor C2 charges; when the third MOS transistor PM2 is conductive, the fourth capacitor C4 charges, and when the third MOS transistor PM2 is non-conductive, the fourth capacitor C4 discharges.

Where the logic comparison unit 300 includes a NAND gate N1, a first input terminal of the NAND gate N1 is connected to the first detection unit 100, and a second input terminal of the NAND gate N1 is connected to the second detection unit 200. The NAND gate N1 outputs a corresponding reset signal based on the first detection voltage IPP and the second detection voltage INN.

That is to say, the first detection voltage IPP and the second detection voltage INN are compared by the NAND gate N1 output of the logic comparison unit 300, and the POR is successfully powered on.

As an embodiment, the logic comparison unit 300 further includes a first inverter 10, a second inverter 20, and a third inverter 30. An input terminal of the first inverter 10 is connected to an output terminal of the first detection unit 100, an output terminal of the first inverter 10 is connected to the first input terminal of the NAND gate N1, an input terminal of the second inverter 20 is connected to an output terminal of the second detection unit 200, an output terminal of the second inverter 20 is connected to an input terminal of the third inverter 30, and an output terminal of the third inverter 30 is connected to the second input terminal of the NAND gate N1.

It should be noted that the inverter ensures that the signal input to the NAND gate N1 matches in timing, eliminates glitches or unstable states, and converts the analog voltage signal generated by capacitor charging and discharging into steep digital logic levels, thereby meeting the logic threshold requirements of the NAND gate N1 for the input signal.

In summary, according to the embodiment of the present disclosure, the power-on reset circuit based on resistance voltage division detection detects the input first bias signal through the first detection unit to obtain the first detection voltage; the second detection unit detects the input second bias signal to obtain the second detection voltage; the logical comparison unit includes the NAND gate, and the first input of the NAND gate is connected to the first detection unit, and the second input of the NAND gate is connected to the second detection unit. The NAND gate outputs a corresponding reset signal based on the first and second detection voltages; as a result, voltage detection is carried out through resistor voltage division, and the detection result is obtained by replacing the comparator with the NAND gate, thereby increasing the power-on speed and reducing the overall circuit area.

In the description of the present disclosure, it should be understood that terms “center”, “longitudinal”, “transverse”, “length”, “width”, “thickness”, “up”, “down”, “front”, “back”, “left”, “right”, “vertical”, “horizontal”, “top”, “bottom”, “inside”, “outside”, “clockwise”, “counterclockwise” and other directional or positional relationships indicated are based on the directional or positional relationships shown in the accompanying drawings, only for the convenience of describing the present disclosure and simplifying the description, and do not indicate or imply that the device or element referred to must have a specific orientation, be constructed and operated in a specific orientation, and therefore cannot understand as a limitation on the present disclosure.

Besides that, terms “first” and “second” are only used for descriptive purposes and cannot be understood as indicating or implying relative importance or implying the number of technical features indicated. Thus, the features limited to “first” and “second” may explicitly or implicitly include one or more of these features. In the description of the present disclosure, “multiple” means two or more, unless otherwise specifically limited.

In the present disclosure, unless otherwise specified and limited, terms “installation”, “connection to”, “connection with”, “fixation”, etc. should be broadly understood, for example, it can be a fixed connection, a detachable connection, or integrated connected; it can be a mechanical connection or an electrical connection; it can be directly connected or indirectly connected through an intermediate medium, and it can be a connection within two components or an interaction relationship between two components. For those skilled in the art, the specific meanings of the above terms in the present disclosure can be understood according to the specific situation.

In the present disclosure, unless otherwise specified and limited, the first feature above or below the second feature may include direct contact between the first and second features, or may include contact between the first and second features through another feature between them instead of direct contact. Moreover, the first feature being “above”, “up”, and “on” the second feature includes the first feature being directly above and diagonally above the second feature, or simply indicating that the first feature is horizontally higher than the second feature. The first feature being “below”, “down”, and “beneath” include the first feature being directly below and diagonally below the second feature, or simply indicating that the first feature has a lower horizontal height than the second feature.

In the description of this specification, the reference to the terms “one embodiment”, “some embodiments”, “examples”, “specific examples”, or “some examples” means that the specific features, structures, materials, or characteristics described in combination with the embodiment or example are included in at least one embodiment or example of the present disclosure. In this specification, the schematic expressions of the above terms should not be understood as necessarily referring to the same embodiments or examples. Moreover, the specific features, structures, materials, or characteristics described can be combined in any one or more embodiments or examples in a suitable manner. Besides that, those skilled in the art can combine and join different embodiments or examples described in this specification.

Although the embodiments of the present disclosure have been shown and described above, it can be understood that the above embodiments are exemplary and should not be construed as limiting the present disclosure. Those skilled in the art can make changes, modifications, substitutions, and variations to the above embodiments within the scope of the present disclosure.

What is claimed is:

1. A power-on reset circuit based on resistance voltage division detection, comprising:
a first detection unit, configured to detect an input first bias signal to obtain a first detection voltage,
a second detection unit, configured to detect an input second bias signal to obtain a second detection voltage, and
a logic comparison unit, which comprises a NAND gate, wherein a first input terminal of the NAND gate is connected to the first detection unit, a second input terminal of the NAND gate is connected to the second detection unit, and the NAND gate outputs a corresponding reset signal based on the first detection voltage and the second detection voltage;
wherein the first detection unit comprises:
a first resistor voltage divider unit, configured to divide and sample an input power supply to obtain a first initial detection voltage,
a first start-up control unit, which is connected to the first resistor voltage divider unit to conduct according to the first initial detection voltage, and
a first charge and discharge unit, which is connected to the first start-up control unit;
after the first start-up control unit is conducted, the first charge and discharge unit obtains a corresponding first detection voltage based on the first bias signal;
wherein the first resistance voltage division unit comprises:
a first resistor, wherein one end of the first resistor is grounded, and
a second resistor, one end of the second resistor is connected to the other end of the first resistor, and the other end of the second resistor is connected to a power source;
wherein the first start-up control unit comprises:
a first capacitor, wherein one end of the first capacitor is connected between the first resistor and the second resistor, and the other end of the first capacitor is grounded, and
a first MOS transistor, wherein a gate of the first MOS transistor is connected between the first resistor and the second resistor, and a source of the first MOS transistor is connected to ground;
wherein the first charge and discharge unit comprises:
a second MOS transistor, wherein a gate of the second MOS transistor is connected to a start-up and bias circuit generator unit to receive the first bias signal, a source of the second MOS transistor is connected to the power supply, and a drain of the second MOS transistor is connected to a drain of the first MOS transistor, and
a second capacitor, wherein one end of the second capacitor is connected to the power supply, and the other end of the second capacitor is connected between the drain of the second MOS transistor and the drain of the first MOS transistor.

2. The power-on reset circuit based on resistance voltage division detection according to claim 1, wherein the second detection unit comprises:
a second resistor voltage divider unit, configured to divide and sample an input power supply to obtain a second initial detection voltage,
a second start-up control unit, which is connected to the second resistor voltage divider unit to conduct according to the second initial detection voltage, and
a second charge and discharge unit, which is connected to the second start-up control unit;
after the second start-up control unit is conducted, the second charge and discharge unit obtains a corresponding second detection voltage based on the second bias signal.

3. The power-on reset circuit based on resistance voltage division detection according to claim 2, wherein the second resistance voltage division unit comprises:
a third resistor, wherein one end of the third resistor is grounded;
a fourth resistor, one end of the fourth resistor is connected to the other end of the third resistor, and the other end of the fourth resistor is connected to the power supply.

4. The power-on reset circuit based on resistance voltage division detection according to claim 3, wherein the second start-up control unit comprises:
a third capacitor, one end of the third capacitor is connected between the third resistor and the fourth resistor, and the other end of the third capacitor is connected to the power supply;
a third MOS transistor, a gate of the third MOS transistor is connected between the third resistor and the fourth resistor, and a source of the third MOS transistor is connected to the power supply.

5. The power-on reset circuit based on resistance voltage division detection according to claim 4, wherein the second charge and discharge unit comprises:
a fourth MOS transistor, wherein a gate of the fourth MOS transistor is connected to a start-up and bias circuit generator unit to receive the second bias signal, a source of the fourth MOS transistor is connected to ground, and a drain of the fourth MOS transistor is connected to a drain of the third MOS transistor;
a fourth capacitor, wherein one end of the fourth capacitor is connected to ground and the other end the fourth capacitor is connected between the drain of the fourth MOS transistor and the drain of the third MOS transistor.

6. The power-on reset circuit based on resistance voltage division detection according to claim 1, wherein the logic comparison unit further comprises a first inverter, a second inverter, and a third inverter,
wherein an input terminal of the first inverter is connected to an output terminal of the first detection unit, an output terminal of the first inverter is connected to the first input terminal of the NAND gate, an input terminal of the second inverter is connected to an output terminal of the second detection unit, an output terminal of the second inverter is connected to an input terminal of the third inverter, and an output terminal of the third inverter is connected to the second input terminal of the NAND gate.
